(19) United States
(12) Patent Application Publication
(10) Pub. No.: US 2026/0143593 A1
(43) Pub. Date: May 21, 2026

(54) PRINTED CIRCUIT BOARD AND SEMICONDUCTOR PACKAGE INCLUDING THE SAME

(71) Applicant: Samsung Electronics Co., Ltd., Suwon-si (KR)

(72) Inventor: Wooyeol LEE, Suwon-si (KR)

(73) Assignee: Samsung Electronics Co., Ltd., Suwon-si (KR)

(21) Appl. No.: 19/225,223

(22) Filed: Jun. 2, 2025

(30) Foreign Application Priority Data
Nov. 15, 2024 (KR) 10-2024-0163366

(51) Int. Cl. H05K 1/18; H05K 1/11

(52) U.S. Cl. CPC H05K 1/181; H05K 1/113; H05K 2201/10159; H05K 2201/10212

(57) ABSTRACT

Provided is a printed circuit board including a substrate base including a first surface and a second surface opposite to the first surface, a wiring on the first surface of the substrate base, and a protection layer configured to cover at least a portion of the first surface of the substrate base, the protection layer is configured to expose at least a portion of the wiring, wherein the protection layer includes a body and a protrusion connected to the body, the protrusion is configured to protrude toward the wiring inside the substrate base, and the protrusion overlaps at least a portion of the wiring in a vertical direction.

### CROSS-REFERENCE TO RELATED APPLICATION

This application is based on and claims priority under 35 U.S.C. § 119 to Korean Patent Application No. 10-2024-0163366, filed on Nov. 15, 2024 in the Korean Intellectual Property office, the disclosure of which is incorporated by reference herein in its entirety.

### BACKGROUND

The inventive concepts relate to printed circuit boards and semiconductor packages including a printed circuit board, and more particularly, to printed circuit boards including an upper wiring and a lower wiring, and semiconductor packages including a printed circuit board.

Recently, demand on portable devices has rapidly increased in the electronic products market, and accordingly, miniaturization and lightweight of the electronic components mounted on the electronic products are continuously required. For the miniaturization and lightweight of the electronic components, the semiconductor packages mounted thereon are required to process a large amount of data while the volume thereof is reduced.

### SUMMARY

The inventive concept provides printed circuit boards having increased reliability and a semiconductor package including the printed circuit board.

In addition, the issues to be solved by the technical idea of the inventive concepts are not limited to those mentioned above, and other issues may be clearly understood by those of ordinary skill in the art from the following descriptions.

According to an aspect of the inventive concepts, there is provided a printed circuit board including a substrate base including a first surface and a second surface opposite to the first surface; a wiring on the first surface of the substrate base; and a protection layer configured to cover at least a portion of the first surface of the substrate base, the protection layer is configured expose, wherein the protection layer includes a body and a protrusion connected to the body, the protrusion is configured to protrude toward the wiring inside the substrate base, and the protrusion overlaps at least a portion of the wiring in a vertical direction.

According to another aspect of the inventive concepts, there is provided a printed circuit board including a substrate base including a first surface and a second surface opposite to the first surface; a first wiring on the first surface of the substrate base; a second wiring on the second surface of the substrate base; a first protection layer configured to cover at least a portion of the first surface of the substrate base, the first protection layer is configured to expose at least a portion of the first wiring; and a second protection layer configured to cover at least a portion of the second surface of the substrate base, the second protection layer is configured to expose at least a portion of the second wiring, wherein the first wiring includes a first connection pad at least partially exposed by the first protection layer and first circuit patterns covered by the first protection layer, the first protection layer includes a first body and a protrusion connected to the first body, the protrusion is configured to protrude from an inside of the substrate base toward the first wiring, and the protrusion overlaps at least a portion of the first wiring in a vertical direction.

According to another aspect of the inventive concepts, there is provided a semiconductor package including a a printed circuit board; and a semiconductor chip mounted on the printed circuit board, the printed circuit board including a substrate base including one or more base layers, the substrate base including a first surface and a second surface opposite to the first surface; a first wiring on the first surface of the substrate base; a second wiring on the second surface of the substrate base; a first protection layer configured to cover at least a portion of the first surface of the substrate base, the first protection layer is configured to expose at least a portion of the first wiring; and a second protection layer configured to cover at least a portion of the second surface of the substrate base, the second protection layer is configured to expose at least a portion of the second wiring, wherein the first protection layer includes a first body and a first protrusion connected to the first body, the first protrusion is configured to protrude from an inside of the substrate base toward the first wiring, and the first protrusion overlaps at least a portion of the first wiring in a vertical direction.

According to another aspect of the inventive concepts, there is provided a method of manufacturing a printed circuit board, the method including forming a substrate base including a first surface and a second surface opposite to the first surface, and including a wiring formed on the first surface, forming a first hole by removing at least a portion of the first surface of the substrate base in a vertical direction, forming, inside the substrate base in a direction where the wiring is formed, a second hole by removing at least a portion of a side wall of the substrate base defining the first hole so that the second hole overlaps at least a portion of the wiring in a vertical direction, and forming a protection layer inside the second hole and on the first surface.

In some example embodiments, the forming of the first hole may be performed by using at least one of a laser method or a blast method.

In some example embodiments, the forming of the first hole may be performed only in a region adjacent to the wiring.

In some example embodiments, the wiring may include a plurality of wiring patterns, and the forming of the first hole may be performed in a region between each of the plurality of wiring patterns.

In some example embodiments, the forming of the first hole may be performed so that one surface defining the first hole may be arranged, in a cross-sectional view, closer to a central axis of the substrate base in a vertical direction than the wiring, the central axis of the substrate base extending in a horizontal direction.

In some example embodiments, the forming of the second hole may be performed, in a cross-sectional view, closer to a central axis of the substrate base in a vertical direction than the wiring by removing a portion of the substrate base in a direction toward the wiring, the central axis of the substrate base extending in a horizontal direction extending in a horizontal direction.

In some example embodiments, the method may further include forming an additional first hole by removing at least a portion of the second surface of the substrate base in the vertical direction, forming an additional second hole by removing at least a portion of a side wall of the substrate base defining the additional first hole inside the substrate base in a direction where an additional wiring on the second surface may be formed, and forming an additional protection layer inside the additional second hole and on the second surface, wherein, and the additional second hole may overlap at least a portion of the additional wiring in the vertical direction.

In some example embodiments, one surface of the second hole extending inside the substrate base in a horizontal direction may be flat.

In some example embodiments, one surface of the second hole extending inside the substrate base in a horizontal direction may have an uneven shape.

### BRIEF DESCRIPTION OF THE DRAWINGS

Some example embodiments will be more clearly understood from the following detailed description taken in conjunction with the accompanying drawings in which:

FIG. 1 is a schematic perspective view of a main board including a semiconductor package according to some example embodiments;

FIG. 2 is a perspective view of a semiconductor package including a printed circuit board according to some example embodiments;

FIG. 3 is a cross-sectional view of a printed circuit board according to some example embodiments;

FIG. 4 is a cross-sectional view of a printed circuit board according to some example embodiments;

FIG. 5 is a cross-sectional view of a printed circuit board according to some example embodiments;

FIG. 6 is a cross-sectional view of a printed circuit board according to some example embodiments;

FIG. 7 is a cross-sectional view of a printed circuit board according to some example embodiments;

FIG. 8 is a cross-sectional view of a printed circuit board according to some example embodiments;

FIG. 9 is a cross-sectional view of a printed circuit board according to some example embodiments;

FIG. 10 is a plan view of an arrangement relationship of a pad and a protrusion of a protection layer, according to some example embodiments;

FIG. 11 is a plan view of an arrangement relationship of a pad and a protrusion of a protection layer, according to some example embodiments;

FIGS. 12 through 14 are cross-sectional views describing a method of manufacturing a printed circuit board, according to some example embodiments;

FIGS. 15 and 16 are cross-sectional views describing a method of manufacturing a printed circuit board, according to some example embodiments; and

FIG. 17 is a block diagram of a computing system including a semiconductor package according to some example embodiments.

### DETAILED DESCRIPTION

Hereinafter, some example embodiments of the inventive concepts are described in detail with reference to the accompanying drawings. Identical reference numerals are used for the same components in the drawings, and a duplicate description thereof will be omitted. In the following drawings, a thickness or size of each layer is exaggerated for convenience and clarity of description, and thus may differ from an actual shape or ratio.

In this case, the terms indicating a position in a space, for example, “under,” “below,” “lower portion,” “over,” and “upper portion,” or the like, are used to explain the relative positional relationship between elements or patterns illustrated in the drawing, only for the purpose of understanding, and do not limit the technical idea of the inventive concept in any sense. Terms for relative positions in a space are intended to cover changes according to the direction of a semiconductor device in addition to the direction disclosed in the drawings. In other words, semiconductor devices may be oriented in various directions when used (or manufactured), and even in such cases, terms for positions used in the inventive concept would be easily understood by those of skill in the art.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

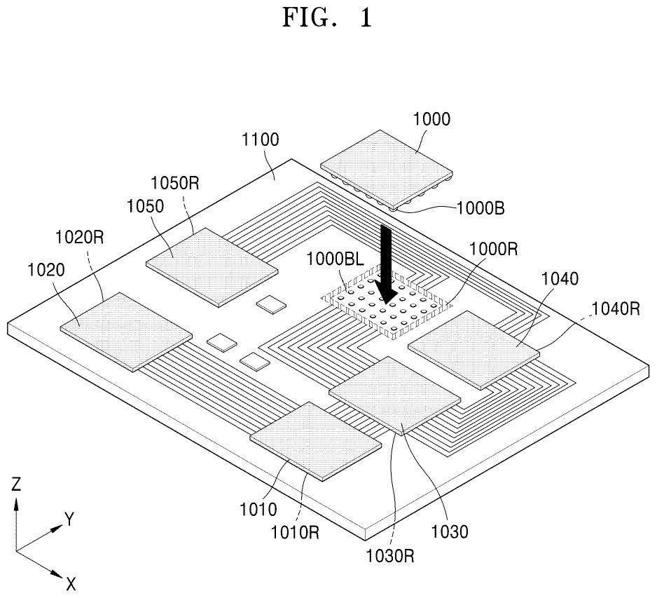

FIG. 1 is a schematic perspective view of a main board 1100 including a semiconductor package according to some example embodiments.

Referring to FIG. 1, the main board 1100 may include various kinds of hardware mounted on an upper surface thereof.

Various kinds of hardware included in the main board 1100 may be mounted in each dedicated region. For example, the main board 1100 may include a dedicated region 1000R of a storage device 1000, a dedicated region 1010R of a host 1010, a dedicated region 1020R of a memory 1020, a dedicated region 1030R of a chipset 1030, a dedicated region 1040R of a graphics processing device 1040, a dedicated region 1050R of a network module 1050, etc. Each of dedicated regions may be electrically connected to each other via various wirings provided on the main board 1100.

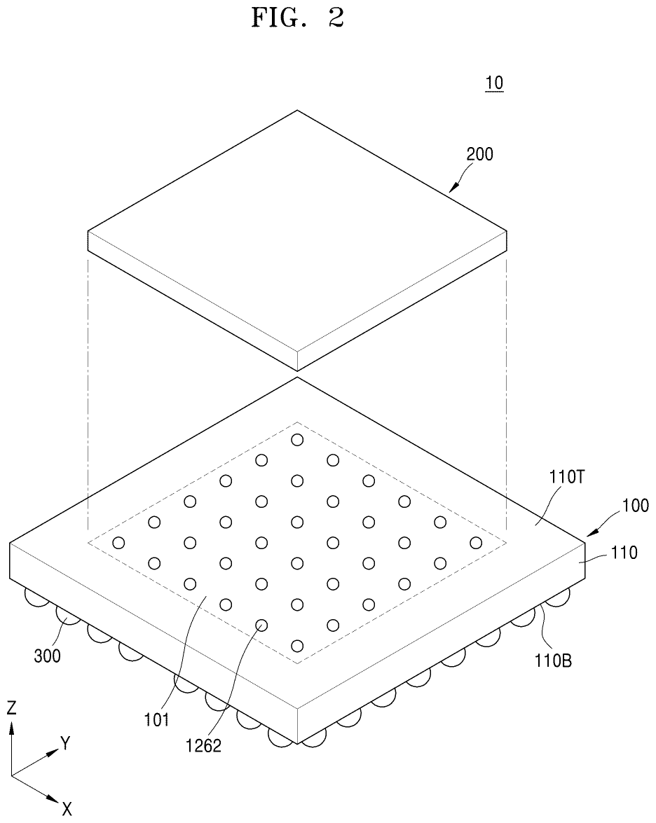

In some example embodiment, the storage device 1000, the host 1010, the memory 1020, the chipset 1030, the graphics processing device 1040, and/or the network module 1050 may be provided to a semiconductor package (refer to 10 in FIG. 2) of a ball grid array (BGA) type. For example, the storage device 1000 may include a solder ball 1000B as an external connection terminal, and may be mounted on the main board 1100 so that a ball land 1000BL and the solder ball 1000B arranged in the dedicated region 1000R are bonded. The storage device 1000 may be mounted on the main board 1100 by using surface mounting technology.

The storage device 1000 may include a single unit or a plurality of units. In some example embodiments, the storage device 1000 may be mounted on a different surface of the main board 1100. For example, one storage device 1000 may be mounted on an upper surface of the main board 1100, and the other storage device 1000 may be mounted on a lower surface of the main board 1100.

The storage device 1000 may transmit program code to the host 1010 by using a sideband protocol. In some example embodiments, the sideband protocol may further include a communication protocol, such as inter-integrated circuit (I2C), management component transport protocol (MCTP), and system management bus (SMBus), that are provided in addition to the communication protocol provided for a normal operation. A detailed description of various hardware is described below.

FIG. 2 is a perspective view of the semiconductor package 10 including a printed circuit board 100 according to some example embodiments.

Referring to FIG. 2, the semiconductor package 10 may include the printed circuit board 100 and a semiconductor chip 200.

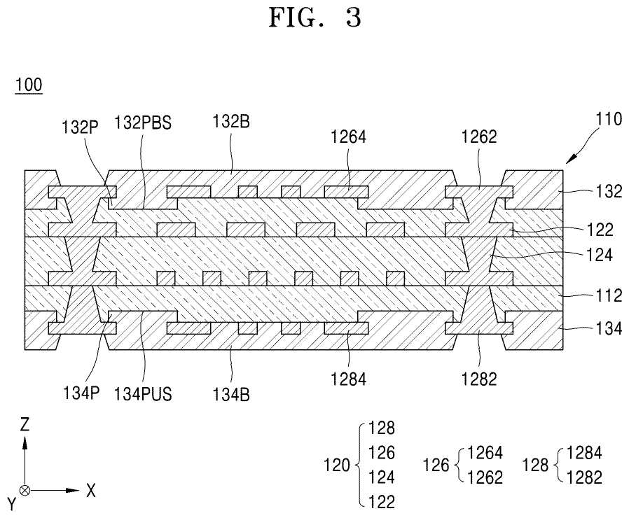

The printed circuit board 100 may include a package substrate. The printed circuit board 100 may include a substrate base 110, an upper connection pad 1262 on an upper surface 110T of the substrate base 110, and a lower connection pad (refer to 1282 in FIG. 3) on a lower surface 110B of the substrate base 110.

The substrate base 110 may form the overall appearance of the printed circuit board 100, and may include at least one material of phenol resin, epoxy resin, and polyimide. An internal interconnection structure (for example, a wiring pattern, a conductive via, or the like) for electrically connecting the upper connection pad 1262 to the lower connection pad (refer to 1282 in FIG. 3) may be provided inside the substrate base 110. The upper connection pad 1262 may be connected to a conductive connection structure (not illustrated) under the semiconductor chip 200, and the lower connection pad (refer to 1282 in FIG. 3) may be connected to an external connection terminal 300, which is an external connection terminal.

The printed circuit board 100 may include a mounting region 101 in which the semiconductor chip 200 is embedded. The mounting region 101 may include a region in which the semiconductor chip 200 is mounted, and the mounting region 101 may substantially overlap the semiconductor chip 200 in a vertical direction (Z direction). Because the mounting region 101 overlaps the semiconductor chip 200 in the vertical direction (Z direction), the mounting region 101 may have the same shape and size as the semiconductor chip 200.

According to some inventive concepts, a direction in parallel with a main surface of the printed circuit board 100 may be defined as a horizontal direction (X direction and/or Y direction), and a direction perpendicular to the horizontal direction (X direction and/or Y direction) may be defined as the vertical direction (Z direction).

In some example embodiments, the semiconductor chip 200 may be mounted on the mounting region 101 of the printed circuit board 100 in a flip chip manner. For example, the semiconductor chip 200 may be connected to the upper connection pad 1262 of the printed circuit board 100 via a connection member, for example, a solder bump, but is not limited thereto. In another example embodiment, the semiconductor chip 200 may be mounted on the mounting region 101 of the printed circuit board 100 by using a bonding wire.

The semiconductor chip 200 may include a logic chip or a memory chip. The memory chip may include, for example, a volatile memory, such as dynamic random access memory (RAM) (DRAM) and static RAM (SRAM), or a non-volatile memory, such as phase-change RAM (PRAM), magnetoresistive RAM (MRAM), ferroelectric RAM (FeRAM), and resistive RAM (RRAM). In addition, the logic chip may include, for example, a microprocessor, an analog device, such as a central processing unit (CPU), a graphics processing unit (GPU), and an application processor (AP), an analog element, or a digital signal processor.

Although the semiconductor package 10 is illustrated to include one semiconductor chip 200 in FIG. 2, the semiconductor package 10 may include a plurality of semiconductor chips 200. In some example embodiments, the semiconductor chip 200 may include a chip stack in which the plurality of semiconductor chips 200 are vertically stacked. For example, the semiconductor chip 200 may include a high bandwidth memory (HBM). In another example embodiment, at least one of the plurality of semiconductor chips 200 may include a memory chip, and another may include a logic chip.

On the other hand, although not illustrated, an underfill material layer may be arranged between the printed circuit board 100 and the semiconductor chip 200. For example, the underfill material layer filling a space between the printed circuit board 100 and the semiconductor chip 200 may be formed by using an underfill process. The underfill material layer may fill the space between the printed circuit board 100 and the semiconductor chip 200, and may surround a connection member arranged between the printed circuit board 100 and the semiconductor chip 200.

FIG. 3 is a cross-sectional view of the printed circuit board 100 according to some example embodiments. FIG. 3 is described with reference to FIG. 2 together.

Referring to FIG. 3, the printed circuit board 100 may include the substrate base 110 and a wiring pattern 120. The substrate base 110 may be formed by stacking one or more base layers 112. FIG. 3 illustrates the substrate base 110 formed by stacking three base layers 112 thereon. However, the number of base layers 112 in the substrate base 110 is not limited thereto.

The base layers 112 may be stacked on each other in the vertical direction (Z direction), and may be provided as a single layer. For example, the base layer 112 may include at least one material of phenol resin, epoxy resin, and/or polyimide. For example, the base layer 112 may include at least one material of flame retardant 4 (FR-4), tetrafunctional epoxy, polyphenylene ether, epoxy/polyphenylene oxide, bismaleimide triazine (BT), thermount, cyanate ester, polyimide, and/or liquid crystal polymer. For example, the base layer 112 may include at least one material of polypropylene glycol (PPG), xylene-based film (XBF), Ajinomoto build-up film (ABF), resin coated copper (RCC), and/or polyimide insulating layer (PID).

The wiring pattern 120 may include a conductive line pattern 122 and a conductive via 124. The conductive line pattern 122 may be on an upper surface and/or a lower surface of the base layer 112, and may extend in a horizontal direction (X direction and/or Y direction). The conductive via 124 may penetrate at least a portion of a plurality of base layers 112 in the vertical direction (Z direction). Each of the conductive line pattern 122 and the conductive via 124 may be provided in plurality, and the conductive via 124 may be connected to some of a plurality of conductive line patterns 122. In some example embodiments, at least some of the plurality of conductive line patterns 122 may be formed together with some of a plurality of conductive vias 124 into one body.

For example, the wiring pattern 120 may include a metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), and ruthenium (Ru), and/or an alloy thereof, but is not limited thereto. In some example embodiments, the wiring pattern 120 may be formed by stacking a metal or an alloy of metals on a seed layer including Ti, titanium nitride, or titanium tungsten. The wiring pattern 120 may be formed by using a plating method. For example, the wiring pattern 120 may be formed by using a plating method, such as emulsion plating, electroless plating, and electroplating.

Among the plurality of conductive line patterns 122, the conductive line pattern 122 on the upper surface of the substrate base 110 may be referred to as an upper wiring 126, and the conductive line pattern 122 on the lower surface of the substrate base 110 may be referred to as a lower wiring 128.

The upper wiring 126 may include an upper connection pad 1262, which is at least partially exposed by an upper protection layer 132, and an upper circuit pattern 1264, which is entirely covered by the upper protection layer 132.

The upper surface protection layer 132 covering at least a portion of the base layer 112 at the uppermost end may be formed on an upper surface of the substrate base 110. In some example embodiments, the upper surface protection layer 132 may cover at least a portion of the upper wiring 126. The upper surface protection layer 132 may cover at least a portion of the upper surface of the substrate base 110.

In addition, a lower surface protection layer 134 covering at least a portion of the base layer 112 at the lowermost end may be formed under a lower surface of the substrate base 110. In some example embodiments, the lower surface protection layer 134 may cover at least a portion of the lower wiring 128. The lower surface protection layer 134 may cover at least a portion of the lower surface of the substrate base 110.

The lower wiring 128 may include a lower connection pad 1282, which is at least partially exposed by the lower surface protection layer 134, and a lower circuit pattern 1284, which is entirely covered by the lower surface protection layer 134.

The upper surface protection layer 132 may include a first protrusion 132P extending in the horizontal direction (X direction and/or Y direction) from a vertical level equal to or lower than a lower surface of a first body 132B and a lower surface of the upper wiring 126 toward the upper wiring 126. In other words, the upper surface protection layer 132 may include the first protrusion 132P extending from the inside of the substrate base 110 to the upper wiring 126 in the horizontal direction (X direction and/or Y direction).

In other words, on the vertical cross-section, the upper surface protection layer 132 may have a C-character shape due to the first body 132B and the first protrusion 132P. The first body 132B and the first protrusion 132P may be formal differentiations only for convenience of description, and the first body 132B and the first protrusion 132P may include the same material and may have a form integrally coupled into one body.

In some example embodiments, at least a portion of the upper surface protection layer 132 may overlap the upper wiring 126 in the vertical direction (Z direction), and may be at a lower vertical level than the lower surface of the upper wiring 126. At least a portion of the first protrusion 132P may overlap the upper wiring 126 in the vertical direction (Z direction). In a plan view, the first protrusion 132P may be arranged between the upper connection pad 1262 and the upper circuit pattern 1264 adjacent to each other. In an some example embodiments, the first protrusion 132P may overlap each of the upper connection pad 1262 and/or the upper circuit pattern 1264 in the vertical direction (Z direction). In some example embodiments, the first protrusion 132P may be in contact with a lower surface of each of the upper connection pad 1262 and/or the upper circuit pattern 1264. Between the upper wirings 126, which are adjacent to each other and in contact with the first protrusions 132P, a lower surface 132PBS of the first protrusion 132P may have a flat shape. In some example embodiments, the lower surface 132PBS between adjacent upper wirings 126 may be coplanar with portions of the lower surface 132PBS that overlap adjacent upper wirings 126 in the vertical direction.

When the upper surface protection layer 132 includes the first protrusion 132P, an adhesion force between the upper surface protection layer 132 and the substrate base 110 may be increased. Accordingly, the reliability of the printed circuit board 100 may be increased.

In some example embodiments, the upper surface protection layer 132 may surround the upper wiring 126. In some example embodiments, the upper surface protection layer 132 may cover at least a portion of each of side surfaces of the upper wiring 126, the lower surface of the upper wiring 126, and the upper surface of the upper wiring 126.

In some example embodiments, the upper surface protection layer 132 may be engaged with the upper wiring 126. In some example embodiments, the upper surface protection layer 132 may be in contact with at least a portion of each of the side surfaces of the upper wiring 126, the lower surface of the upper wiring 126, and the upper surface of the upper wiring 126. For example, at least a portion of the first body 132B may be in contact with the upper surface of the upper wiring 126 and the side surfaces of the upper wiring 126, and at least a portion of the first protrusion 132P may be in contact with the lower surface of the upper wiring 126. In another example embodiment, the upper surface protection layer 132 may be apart from the side surfaces of the upper wiring 126 in the horizontal direction (X direction and/or Y direction).

In some example embodiments, the upper surface of the upper surface protection layer 132 may be at a higher vertical level than the upper surface of the upper wiring 126, and the lowermost surface of the upper surface protection layer 132 may be at a lower vertical level than the lower surface of the upper wiring 126. In other words, one surface of the upper surface protection layer 132 may be arranged more inside the substrate base 110 than the upper wiring 126 in the vertical direction (Z direction).

The lower surface protection layer 134 may include a second protrusion 134P extending in the horizontal direction (X direction and/or Y direction) toward the lower wiring 128 from a vertical level equal to or higher than upper surfaces of a second body 134B and the lower wiring 128. In other words, the lower surface protection layer 134 may include the second protrusion 134P extending from the inside of the substrate base 110 to the lower wiring 128 in the horizontal direction (X direction and/or Y direction).

In other words, on the vertical cross-section, the lower surface protection layer 134 may have a C-character shape due to the second body 134B and the second protrusion 134P. The second body 134B and the second protrusion 134P may be formal differentiations only for convenience of description, and the second body 134B and the second protrusion 134P may include the same material and may have a form integrally coupled into one body.

In some example embodiments, at least a portion of the lower surface protection layer 134 overlaps the lower wiring 128 in the vertical direction (Z direction), and may be at a higher vertical level than the upper surface of the lower wiring 128. At least a portion of the second protrusion 134P may overlap the lower wiring 128 in the vertical direction (Z direction). In a plan view, the second protrusion 134P may be arranged between the lower connection pad 1282 and the lower circuit pattern 1284 adjacent to each other. In some example embodiments, the second protrusion 134P may overlap each of the lower connection pad 1282 and/or the lower circuit pattern 1284 in the vertical direction (Z direction). In some example embodiments, the second protrusion 134P may be in contact with an upper surface of each of the lower connection pad 1282 and/or the lower circuit pattern 1284. Between the lower wirings 128, which are adjacent to each other and in contact with the second protrusions 134P, an upper surface 134PUS of the second protrusion 134P may have a flat shape. In some example embodiments, the upper surface 134PUS between adjacent lower wirings 128 may be coplanar with portions of the upper surface 134PUS that overlap adjacent lower wirings 128 in the vertical direction.

When the lower surface protection layer 134 includes the second protrusion 134P, the adhesion force between the lower surface protection layer 134 and the substrate base 110 may be increased. Accordingly, the reliability of the printed circuit board 100 may be increased.

In some example embodiments, the lower surface protection layer 134 may surround the lower wiring 128. In some example embodiments, the lower surface protection layer 134 may cover at least a portion of each of the side surfaces of the lower wiring 128, a lower surface of the lower wiring 128, and an upper surface of the lower wiring 128.

In some example embodiments, the lower surface protection layer 134 may be coupled with the lower wiring 128. In some example embodiments, the lower surface protection layer 134 may be in contact with at least a portion of each of the upper surface of the lower wiring 128, the side surfaces of the lower wiring 128, and the lower surface of the lower wiring 128. For example, at least a part of the second body 134B may be in contact with the lower surface of the lower wiring 128 and the side surfaces of the lower wiring 128, and at least a portion of the second protrusion 134P may be in contact with the upper surface of the lower wiring 128. In another example embodiment, the lower surface protection layer 134 may be apart from the side surfaces of the lower wiring 128 in the horizontal direction (X direction and/or Y direction).

In some example embodiments, the lower surface of the lower surface protection layer 134 may be at a lower vertical level than the lower surface of the lower wiring 128, and the uppermost surface of the lower surface protection layer 134 may be at a higher vertical level than the upper surface of the lower wiring 128. In other words, one surface of the lower surface protection layer 134 may be more inside the substrate base 110 than the lower wiring 128 in the vertical direction (Z direction).

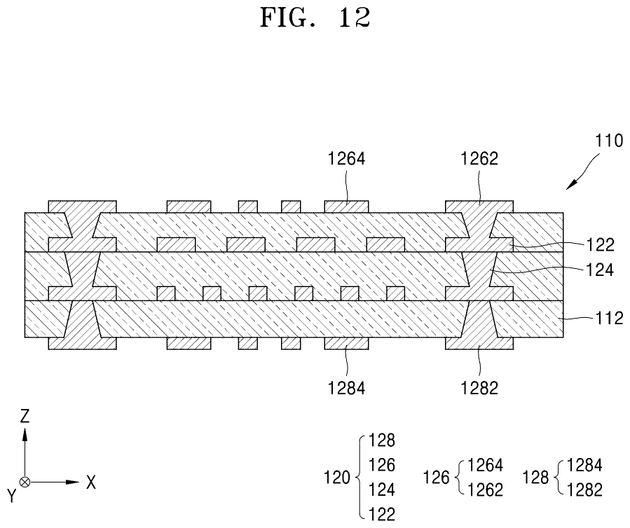

A method of forming the upper surface protection layer 132 and the lower surface protection layer 134 in FIG. 3 is described in detail below with reference to FIGS. 12 through 14.

The semiconductor chip 200 may be mounted on an upper surface of the printed circuit board 100. In other words, the upper surface of the printed circuit board 100 may include a chip mounting surface. An external connection terminal 300 may be attached to a lower surface of the printed circuit board 100. In other words, the lower surface of the printed circuit board 100 may include a connection terminal attachment surface. The semiconductor chip 200 may be electrically connected to the upper wiring 126. For example, the semiconductor chip 200 may be electrically and/or physically connected to the upper connection pad 1262. In addition, the external connection terminal 300 may be electrically connected to the lower wiring 128. For example, the external connection terminal 300 may be electrically and/or physically connected to the lower connection pad 1282.

The upper surface protection layer 132 of the printed circuit board 100 of the inventive concepts may include a protrusion protruding from the inside of the substrate base 110 toward the upper wiring 126. In addition, the lower surface protection layer 134 may include a protrusion protruding from the inside of the substrate base 110 toward the lower wiring 128. Accordingly, the adhesion force between the upper surface protection layer 132 and the substrate base 110 may be increased, and the adhesion force between the lower surface protection layer 134 and the substrate base 110 may be increased. Accordingly, the possibility that the upper surface protection layer 132 is peeled off from the substrate base 110 may be reduced in likelihood. In addition, a phenomenon in which the lower surface protection layer 134 is peeled off from the substrate base 110 may be reduced in likelihood. Accordingly, a phenomenon in which a connection member connected to the upper connection pad 1262 is extruded may be reduced in likelihood. In addition, a phenomenon in which the external connection terminal 300 connected to the lower connection pad 1282 is extruded may be reduced in likelihood. Thus, the reliability of the printed circuit board 100 may be increased.

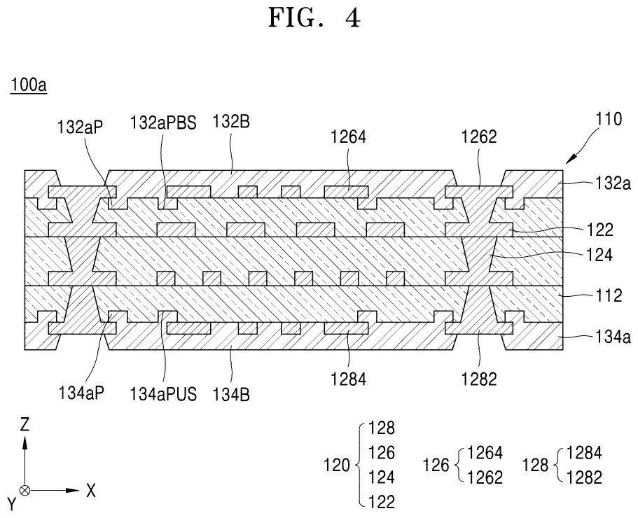

FIG. 4 is a cross-sectional view of a printed circuit board 100a according to some example embodiments. FIG. 4 is described with reference to FIG. 3 together.

The printed circuit board 100a of FIG. 4 may be substantially the same as the printed circuit board 100 of FIG. 3, except that an upper surface protection layer 132a and a lower surface protection layer 134a are respectively different from the upper surface protection layer 132 and the lower surface protection layer 134 of the printed circuit board 100 of FIG. 3. Accordingly, descriptions are given mainly based on the upper surface protection layer 132a and the lower surface protection layer 134a.

Referring to FIG. 4, the upper surface protection layer 132a may include a first protrusion 132aP, and the lower surface protection layer 134a may include a second protrusion 134aP. Between the upper wirings 126, which are adjacent to each other and in contact with the first protrusions 132aP, a lower surface 132aPBS of the first protrusion 132aP may have an uneven shape. In some example embodiments, the lower surface 132aPBS between adjacent upper wirings 126 may not be coplanar with portions of the lower surface 132aPBS that overlap adjacent upper wirings 126 in the vertical direction. Between the lower wirings 128, which are adjacent to each other and in contact with the second protrusions 134aP, an upper surface 134aPUS of the second protrusion 134aP may have an uneven shape. In some example embodiments, the upper surface 134aPUS between adjacent lower wirings 128 may not be coplanar with portions of the upper surface 134aPUS that overlap adjacent lower wirings 128 in the vertical direction.

A method of forming the upper surface protection layer 132a and the lower surface protection layer 134a in FIG. 3 is described in detail below with reference to FIGS. 12, 15, and 16.

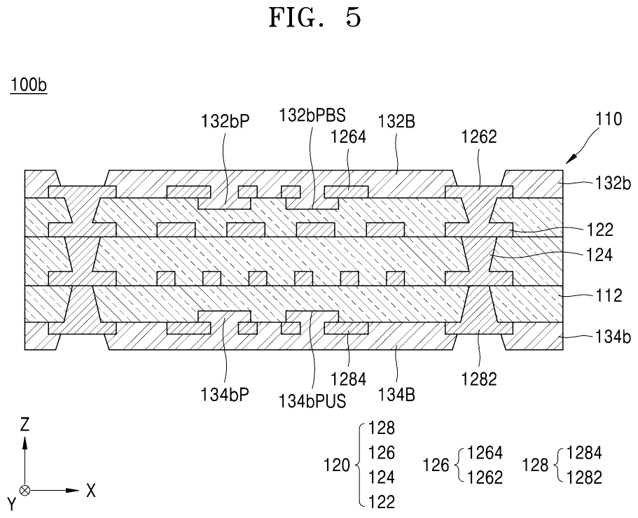

FIG. 5 is a cross-sectional view of a printed circuit board 100b according to some example embodiments. FIG. 5 is described with reference to FIG. 3 together.

The printed circuit board 100b of FIG. 5 may be substantially the same as the printed circuit board 100 of FIG. 3, except that an upper surface protection layer 132b and a lower surface protection layer 134b are respectively different from the upper surface protection layer 132 and the lower surface protection layer 134 of FIG. 3. Accordingly, descriptions are given mainly based on the upper surface protection layer 132b and the lower surface protection layer 134b.

Referring to FIG. 5, the upper surface protection layer 132b may include a first protrusion 132bP, and the lower surface protection layer 134b may include a second protrusion 134bP. In a plan view, the first protrusion 132bP may be arranged between the upper circuit patterns 1264 adjacent to each other, and in a plan view, the second protrusion 134bP may be arranged between the lower circuit patterns 1284 adjacent to each other.

The first protrusion 132bP may overlap at least two of the upper circuit patterns 1264 adjacent to each other in the vertical direction (Z direction), and the second protrusion 134bP may overlap at least two of the lower circuit patterns 1284 adjacent to each other in the vertical direction (Z direction). The first protrusion 132bP may overlap at least two of the upper circuit patterns 1264 adjacent to each other, and the second protrusion 134bP may overlap at least two of the lower circuit patterns 1284 adjacent to each other.

Between the upper wirings 126, which are adjacent to each other and in contact with the first protrusions 134bP, a lower surface 132bPBS of the first protrusion 132bP may have a flat shape. In some example embodiments, the lower surface 132bPBS between adjacent upper wirings 126 may be coplanar with portions of the lower surface 132bPBS that overlap adjacent upper wirings 126 in the vertical direction. Between the lower wirings 128, which are adjacent to each other and in contact with the second protrusions 134bP, an upper surface 134bPUS of the second protrusion 134bP may have a flat shape. In some example embodiments, the upper surface 134bPUS between adjacent lower wirings 128 may be coplanar with portions of the upper surface 134bPUS that overlap adjacent lower wirings 128 in the vertical direction.

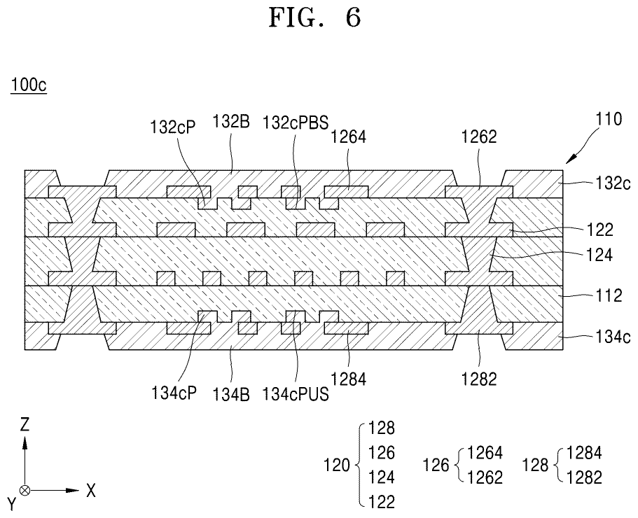

FIG. 6 is a cross-sectional view of a printed circuit board 100c according to some example embodiments. FIG. 6 is described with reference to FIGS. 3 and 5 together.

The printed circuit board 100c of FIG. 6 may be substantially the same as the printed circuit board 100 of FIG. 3, except that an upper surface protection layer 132c and a lower surface protection layer 134c are respectively different from the upper surface protection layer 132 and the lower surface protection layer 134 of the printed circuit board 100 of FIG. 3. Accordingly, descriptions are given mainly based on the upper surface protection layer 132c and the lower surface protection layer 134c.

Referring to FIG. 6, the upper surface protection layer 132c may include a first protrusion 132cP, and the lower surface protection layer 134c may include a second protrusion 134cP. In a plan view, the first protrusion 132cP may be arranged between the upper circuit patterns 1264 adjacent to each other, and in a plan view, the second protrusion 134cP may be arranged between the lower circuit patterns 1284 adjacent to each other.

The first protrusion 132cP may overlap at least two of the upper circuit patterns 1264 adjacent to each other in the vertical direction (Z direction), and the second protrusion 134cP may overlap at least two of the lower circuit patterns 1284 adjacent to each other in the vertical direction (Z direction). The first protrusion 132cP may overlap at least two of the upper circuit patterns 1264 adjacent to each other, and the second protrusion 134cP may overlap at least two of the lower circuit patterns 1284 adjacent to each other.

Between the upper wirings 126, which are adjacent to each other and in contact with the first protrusions 132cP, a lower surface 132cPBS of the first protrusion 132cP may have an uneven shape. In some example embodiments, the lower surface 132cPBS between adjacent upper wirings 126 may not be coplanar with portions of the lower surface 132cPBS that overlap adjacent upper wirings 126 in the vertical direction. Between the lower wirings 128, which are adjacent to each other and in contact with the second protrusions 134cP, an upper surface 134cPUS of the second protrusion 134bP may have an uneven shape. In some example embodiments, the upper surface 134cPUS between adjacent lower wirings 128 may not be coplanar with portions of the upper surface 134cPUS that overlap adjacent lower wirings 128 in the vertical direction.

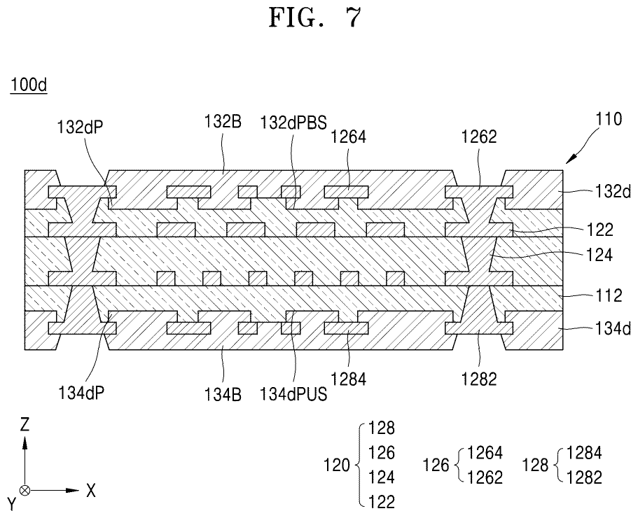

FIG. 7 is a cross-sectional view of a printed circuit board 100d according to some example embodiments. FIG. 7 is described with reference to FIGS. 3 and 5 together.

The printed circuit board 100d of FIG. 7 may be substantially the same as the printed circuit board 100 of FIG. 3, except that an upper surface protection layer 132d and a lower surface protection layer 134d are respectively different from the upper surface protection layer 132 and the lower surface protection layer 134 of the printed circuit board 100 of FIG. 3. Accordingly, descriptions are given mainly based on the upper surface protection layer 132d and the lower surface protection layer 134d.

Referring to FIG. 7, the upper surface protection layer 132d may include a first protrusion 132dP, and the lower surface protection layer 134d may include a second protrusion 134dP. In some example embodiments, the first protrusion 132dP may include two or more protrusions. In a plan view, the first protrusion 132dP may be arranged between the upper circuit patterns 1264 adjacent to each other, and in a plan view, the second protrusion 134dP may be arranged between the lower circuit patterns 1284 adjacent to each other. In some example embodiments, the second protrusion 132dP may include two or more protrusions.

In a plan view, the first protrusion 132dP may be arranged between the upper connection pad 1262 and the upper circuit pattern 1264, and in a plan view, the second protrusion 134dP may be arranged between the lower connection pad 1282 and the lower circuit pattern 1284, which are adjacent to each other. In addition, the first protrusion 132dP may be arranged between the upper circuit patterns 1264 adjacent to each other, and in a plan view, the second protrusion 134dP may be arranged between the lower circuit patterns 1284 adjacent to each other.

In other words, the first protrusion 132dP may overlap each of the upper connection pad 1262 and/or the upper circuit pattern 1264 in the vertical direction (Z direction), which are adjacent to each other. In addition, the first protrusion 132dP may overlap at least two of the upper circuit patterns 1264 adjacent to each other in the vertical direction (Z direction). For example, in some example embodiments, one first protrusion 132dP may overlap the upper connection pad 1262 and an upper circuit pattern 1264 in the vertical direction (Z direction), which are adjacent to each other, and a second first protrusion 132dP may overlap two of the upper circuit patterns 1264 in the vertical direction (Z direction). In some example embodiments, the second protrusion 134dP may include at least two protrusions such that one second protrusion 134dP may overlap the lower connection pad 1282 and the lower circuit pattern 1284 in the vertical direction (Z direction) and one second protrusion 134dP may overlap two of the lower circuit patterns 1284 in the vertical direction.

In other words, the second protrusion 134dP may overlap each of the lower connection pad 1282 and/or the lower circuit pattern 1284 in the vertical direction (Z direction), which are adjacent to each other. In addition, the first protrusion 132dP may overlap at least two of the lower circuit patterns 1284 adjacent to each other in the vertical direction (Z direction).

Between the upper wirings 126, which are adjacent to each other and in contact with the first protrusions 132dP, a lower surface 132dPBS of the first protrusion 132dP may have a flat shape. In some example embodiments, the lower surface 132dPBS between adjacent upper wirings 126 may be coplanar with portions of the lower surface 132dPBS that overlap adjacent upper wirings 126 in the vertical direction. Between the lower wirings 128, which are adjacent to each other and in contact with the second protrusions 134P, an upper surface 134dPUS of the second protrusion 134dP may have a flat shape. In some example embodiments, the upper surface 134dPUS between adjacent lower wirings 128 may be coplanar with portions of the upper surface 134dPUS that overlap adjacent lower wirings 128 in the vertical direction.

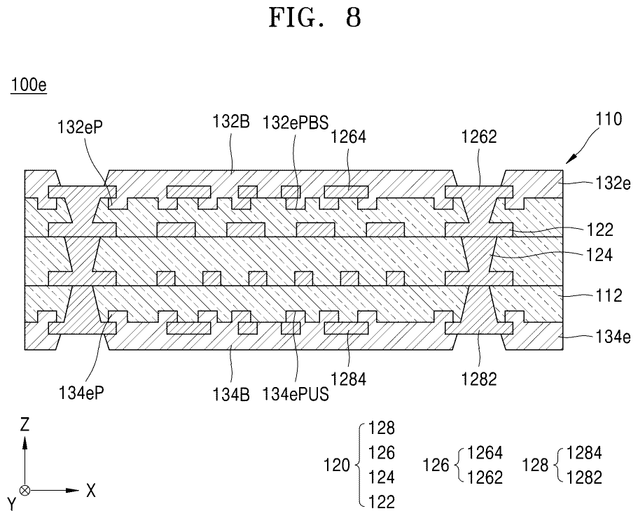

FIG. 8 is a cross-sectional view of a printed circuit board 100e according to some example embodiments. FIG. 8 is described with reference to FIGS. 3 and 7 together.

The printed circuit board 100e of FIG. 8 may be substantially the same as the printed circuit board 100 of FIG. 3, except that an upper surface protection layer 132e and a lower surface protection layer 134e are respectively different from the upper surface protection layer 132 and the lower surface protection layer 134 of the printed circuit board 100 of FIG. 3. Accordingly, descriptions are given mainly based on the upper surface protection layer 132e and the lower surface protection layer 134e.

Referring to FIG. 8, the upper surface protection layer 132e may include a first protrusion 132eP, and the lower surface protection layer 134e may include a second protrusion 134eP. In some example embodiments, the first protrusion 132eP may refer to two or more protrusions. In a plan view, the first protrusion 132eP may be arranged between the upper circuit patterns 1264 adjacent to each other, and in a plan view, the second protrusion 134eP may be arranged between the lower circuit patterns 1284 adjacent to each other. In some example embodiments, the second protrusion 134eP may refer to two or more protrusions.

In a plan view, the first protrusion 132eP may be arranged between the upper connection pad 1262 and the upper circuit pattern 1264, and in a plan view, the second protrusion 134eP may be arranged between the lower connection pad 1282 and the lower circuit pattern 1284, which are adjacent to each other. In addition, the first protrusion 132eP may be arranged between the upper circuit patterns 1264 adjacent to each other, and in a plan view, the second protrusion 134eP may be arranged between the lower circuit patterns 1284 adjacent to each other.

In other words, the first protrusion 132eP may overlap each of the upper connection pad 1262 and/or the upper circuit pattern 1264 in the vertical direction (Z direction), which are adjacent to each other. In addition, the first protrusion 132eP may overlap at least two of the upper circuit patterns 1264 adjacent to each other in the vertical direction (Z direction). For example, in some example embodiments, one first protrusion 132eP may overlap the upper connection pad 1262 and an upper circuit pattern 1264 in the vertical direction (Z direction) and a second first protrusion 132eP may overlap two of the upper circuit patterns 1264 in the vertical direction (Z direction). In some example embodiments, the second protrusion 134eP may include at least two protrusions such that one second protrusion 134eP may overlap the lower connection pad 1282 and the lower circuit pattern 1284 in the vertical direction (Z direction) and one second protrusion 134eP may overlap two of the lower circuit patterns 1284 in the vertical direction.

In other words, the second protrusion 134eP may overlap each of the lower connection pad 1282 and/or the lower circuit pattern 1284 in the vertical direction (Z direction), which are adjacent to each other. In addition, the second protrusion 134eP may overlap at least two of the lower circuit patterns 1284 adjacent to each other in the vertical direction (Z direction).

A lower surface 132ePBS of the first protrusion 132eP may have an uneven shape. In some example embodiments, the lower surface 132ePBS between adjacent upper wirings 126 may not be coplanar with portions of the lower surface 132ePBS that overlap adjacent upper wirings 126 in the vertical direction. In addition, an upper surface 134ePUS of the second protrusion 134eP may have an uneven shape. In some example embodiments, the upper surface 134ePUS between adjacent lower wirings 128 may not be coplanar with portions of the upper surface 134ePUS that overlap adjacent lower wirings 128 in the vertical direction.

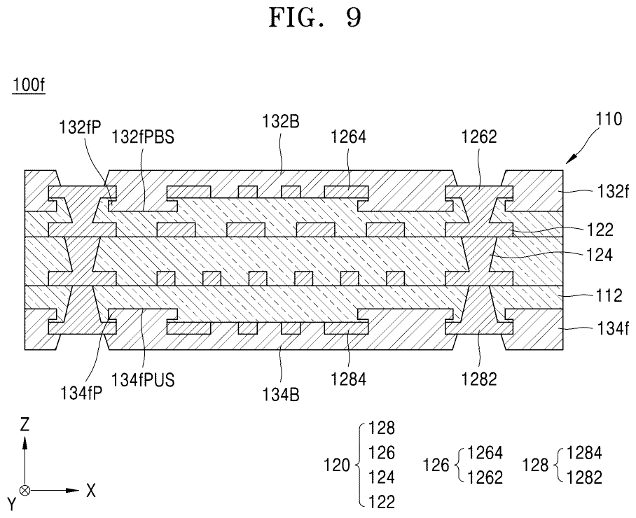

FIG. 9 is a cross-sectional view of a printed circuit board 100f according to an some example embodiments. FIG. 9 is described with reference to FIG. 3 together.

The printed circuit board 100f of FIG. 9 may be substantially the same as the printed circuit board 100 of FIG. 3, except that an upper surface protection layer 132f and a lower surface protection layer 134f are respectively different from the upper surface protection layer 132 and the lower surface protection layer 134 of the printed circuit board 100 of FIG. 3. Accordingly, descriptions are given mainly based on the upper surface protection layer 132f and the lower surface protection layer 134f.

Referring to FIG. 9, the upper surface protection layer 132f may include a first protrusion 132fP, and the lower surface protection layer 134f may include a second protrusion 134fP.

The first protrusion 132fP of the upper surface protection layer 132f may be apart from the upper wiring 126 in the vertical direction (Z direction). The first protrusion 132fP may be at a lower vertical level than the upper wiring 126. In addition, the second protrusion 134fP of the lower surface protection layer 134f may be apart from the lower wiring 128 in the vertical direction (Z direction). The second protrusion 134fP may be at a higher vertical level than the lower wiring 128.

Between the first protrusion 132fP and the upper wiring 126 in contact therewith, which are adjacent to each other, a lower surface 132fPBS of the first protrusion 132fP may have a flat shape. In some example embodiments, the lower surface 132fPBS between adjacent upper wirings 126 may be coplanar with portions of the lower surface 132fPBS that overlap adjacent upper wirings 126 in the vertical direction. Between the lower wirings 128, which are adjacent to each other and overlap the second protrusions 134fP, an upper surface 134fPUS of the second protrusion 134fP may have a flat shape. In some example embodiments, the upper surface 134fPUS between adjacent lower wirings 128 may be coplanar with portions of the upper surface 134fPUS that overlap adjacent lower wirings 128 in the vertical direction.

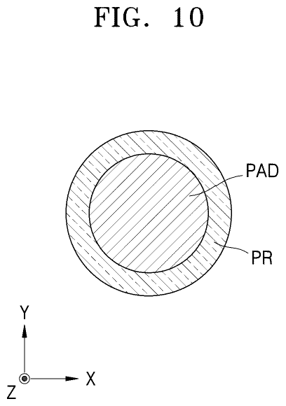

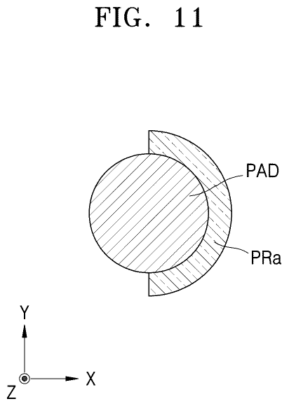

FIG. 10 is a plan view of an arrangement relationship between a pad PAD and a protrusion of a protection layer, according to some example embodiments. FIG. 11 is a plan view of an arrangement relationship between the pad PAD and a protrusion PR of a protection layer, according to some example embodiments. For convenience of explanation, only the protrusions of the protection layer are shown. FIGS. 10 and 11 are described with reference to FIG. 3 together.

Referring to FIG. 10, in a plan view, the protrusion PR may surround the pad PAD. In some example embodiments, in a plan view, the protrusion PR may surround the entire outer surface of the pad PAD.

Referring to FIG. 11, in a plan view, the protrusion PRa may surround the pad PAD. In some example embodiments, in a plan view, the protrusion PRa may surround at least a portion of the entire outer surface of the pad PAD. In other words, in a plan view, the protrusion PRa may surround at least a portion of the outer surface of the pad PAD, and may not surround at least a portion of the remaining outer surface thereof.

FIGS. 12 through 14 are cross-sectional views describing methods of manufacturing a printed circuit board, according to some example embodiments. FIGS. 12 through 14 are cross-sectional views describing methods of forming the printed circuit board 100 of FIG. 3. FIGS. 12 through 14 are described with reference to FIGS. 3, 5, 7, and 9 together.

Referring to FIG. 12, the substrate base 110 formed by stacking one or more base layers 112 including the wiring pattern 120 formed therein may be formed. The wiring pattern 120 may include the conductive line pattern 122 on an upper surface and/or a lower surface of one or more base layers 112, and a plurality of conductive vias 124, which penetrate at least a portion of the one or more base layers 112 in the vertical direction (Z direction), and are connected to at least some of the plurality of conductive line patterns 122.

To form the substrate base 110, firstly, the conductive line pattern 122 may be formed by using a plating process. For example, after a seed metal layer is formed, the conductive line pattern 122 may be formed by performing the plating process using the seed metal layer. After the conductive line pattern 122 is formed, a first operation of forming an insulating layer covering the conductive line pattern 122 and including a via hole, and a second operation of forming the conductive via 124 filling the via hole of the insulating layer, and the conductive line pattern 122 extending along an upper surface of the insulating layer may be performed. The second operation of forming the conductive line pattern 122 and the conductive via 124 may include a plating process using the seed metal layer.

When the substrate base 110 includes the plurality of base layers 112, the substrate base 110 having a multi-layer wiring structure may be formed by repeatedly performing the first operation of forming the insulating layer and the second operation of forming the conductive line pattern 122 and the conductive via 124.

As described above, among the plurality of conductive line patterns 122, some conductive line patterns 122 on the upper surface of the substrate base 110 may be referred to as upper wirings 126, and among the plurality of conductive line patterns 122, some conductive line patterns 122 on the lower surface of the substrate base 110 may be referred to as lower wirings 128.

As described above, among the upper wirings 126, at least some thereof that are later exposed by the upper surface protection layer 132 may be referred to as upper connection pads 1262, and among the upper wirings 126, some thereof that are later entirely covered by the upper surface protection layer 132 may be referred to as upper connection pads 1264. Among the lower wirings 128, at least some thereof that are later exposed by the lower surface protection layer 134 may be referred to as lower connection pads 1282, and among the upper wirings 128, some thereof that are later entirely covered by the lower surface protection layer 134 may be referred to as lower connection pads 1284.

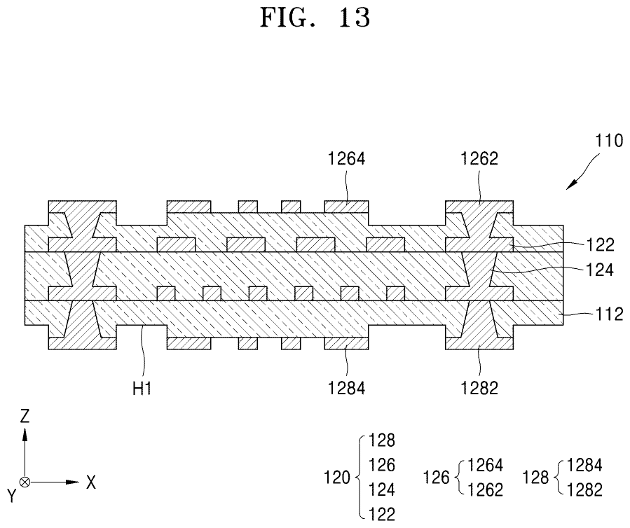

Referring to FIG. 13, at least a portion of the base layer 112 at the uppermost end exposed by the upper wiring 126 and/or at portion of the base layer 112 at the lowermost end exposed by the lower wiring 128 may be removed. At least a portion of the base layer 112 may be removed to form a first hole H1. In some example embodiments, multiple portions of the base layer 112 may be removed to form one or more first holes H1. At least a portion of the base layer 112 at the uppermost end exposed between each of a plurality of upper wirings 126 adjacent to each other and/or between each of a plurality of lower wirings 128 adjacent to each other may be removed to form the first hole H1.

A lower surface of the first hole H1 (e.g., a lower surface of the base layer 112 at least partially defining the first hole H1) formed adjacent to the upper surface of the substrate base 110 may be at a lower vertical level than the lower surface of the upper wiring 126. In addition, an upper surface of the first hole H1 (e.g., an upper surface of the base layer 112 at least partially defining the first hole H1) formed adjacent to the lower surface of the substrate base 110 may be at a higher vertical level than the upper surface of the lower wiring 128. In other words, one surface of the first hole H1 (e.g., one surface of the base layer 112 at least partially defining the first hole H1) may be arranged more inside the substrate base 110 than the wiring in the vertical direction (Z direction).

Side surfaces of the first hole H1 (e.g., side surfaces of the base layer 112 at least partially defining the first hole H1) may extend in the vertical direction (Z direction). In some example embodiments, the side surfaces of the first hole H1 may be aligned (e.g., coplanar) with side surfaces of the upper wiring 126 and/or side surfaces of the lower wiring 128 in the vertical direction (Z direction). In another example embodiment, the side surfaces of the first hole H1 may be aligned (e.g., coplanar) with the side surfaces of the upper wiring 126 and/or the side surfaces of the lower wiring 128 in the horizontal direction (X direction and/or Y direction).

In some example embodiments, at least a portion of the base layer 112 may be removed by a laser. For example, at least a portion of the base layer 112 may be removed by using a CO₂ laser and/or an ultraviolet (UV) laser. In another example embodiment, at least a portion of the base layer 112 may be removed by using a blast method. For example, when the base layer 112 having a large area is removed, the blast method may be used.

FIG. 13 illustrates that the base layer 112 between the upper connection pad 1262 and the upper circuit pattern 1264 adjacent to each other is removed, or the base layer 112 between the lower connection pad 1282 and the lower circuit pattern 1284 adjacent to each other is removed, but the technical idea of the inventive concepts is not limited thereto.

For example, the base layer 112 between the upper circuit patterns 1264 adjacent to each other may be removed, or the base layer 112 between the lower connection pad 1282 and the lower circuit pattern 1284 adjacent to each other may be removed. In this case, the printed circuit board 100b of FIG. 5 or the printed circuit board 100d of FIG. 7 may be formed.

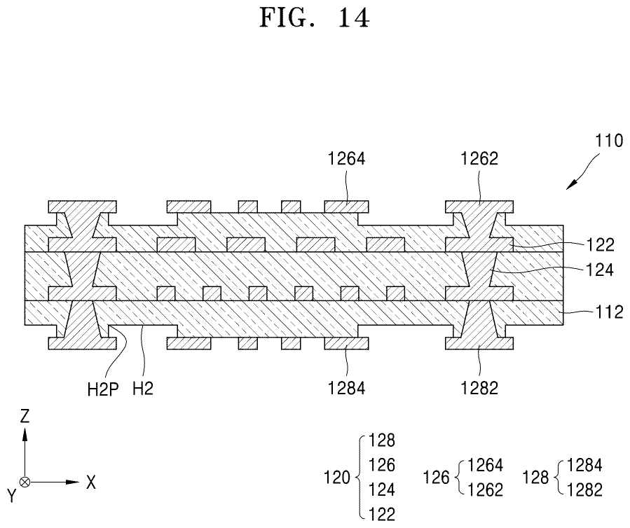

Referring to FIG. 14, at least a portion of the base layer 112 may be further removed. In some example embodiments, at least a portion of the base layer 112 may be removed by using a desmear process. At least a portion of the base layer 112 may be further removed to form a second hole H2. The second hole H2 may provide a space for forming the upper surface protection layer 132 and/or the lower surface protection layer 134 later.

In some example embodiments, at least a portion of the second hole H2 may overlap the upper wiring 126 and/or the lower wiring 128 in the vertical direction (Z direction). In a plan view, the second hole H2 may further include the first hole H1 and a protrusion cavity H2P protruding in a direction where the upper wiring 126 and/or the lower wiring 128 are arranged. The protrusion cavity H2P may extend in the horizontal direction (X direction and/or Y direction). The protrusion cavity H2P may provide spaces for forming the first protrusion 132P and/or the second protrusion 134P described above with reference to FIG. 3.

In some example embodiments, the second hole H2 may be in contact with (e.g., at least partially defined by) the lower surface of the upper wiring 126 and/or the upper surface of the lower wiring 128. The protrusion cavity H2P of the second hole H2 may be in contact with (e.g., at least partied defined by) the lower surface of the upper wiring 126 and/or the upper surface of the lower wiring 128. In some example embodiments, the second hole H2 may be in contact with (e.g., at least partially defined by) at least a portion of the lower surface of each of the upper connection pad 1262 and the upper circuit pattern 1264 adjacent to each other. In addition, the second hole H2 may be in contact with (e.g., at least partially defined by) at least a portion of the upper surface of each of the lower connection pad 1282 and the lower circuit pattern 1284 adjacent to each other. One surface of the second hole H2 may extend in the horizontal direction (X direction and/or Y direction) inside the substrate base 110. In addition, the side surfaces of the protrusion cavity H2P may extend in the vertical direction (Z direction).

In some example embodiments, the second hole H2 may be spaced apart from the lower surface of the upper wiring 126 and/or the upper surface of the lower wiring 128 in the vertical direction (Z direction). That is to say, in some example embodiments, a portion of the base layer 112 may extend between the protrusion cavity H2P and a bottom surface of the upper wiring 126 or a top surface of the lower wiring 128. The protrusion H2P of the second hole H2 may be apart from the lower surface of the upper wiring 126 and/or the upper surface of the lower wiring 128 in the vertical direction (Z direction). In this case, the printed circuit board 100f of FIG. 9 may be formed.

Thereafter, a solder resist may be doped on the inside of the second hole H2, and on each of at least portions of the upper surface of the base layer 112 at the uppermost portion and/or the lower surface of the base layer 112 at the lowermost portion. In some example embodiments, a solder resist of a liquid phase type or half-hardened solid type may be doped on the inside of the second hole H2, and on each of at least portions of the upper surface of the base layer 112 at the uppermost portion and/or the lower surface of the base layer 112 at the lowermost portion. In some example embodiments, a solder resist may include an insulation material. After the solder resist is doped, the upper surface protection layer 132 and/or the lower surface protection layer 134 may be formed. Accordingly, the printed circuit board 100 of FIG. 3 may be formed.

Inside the substrate base 110, because one surface of the second hole H2 (e.g., a surface of the base layer 112 at least partially defining the second hole) extending in the horizontal direction (X direction and/or Y direction) has a flat shape, and the one surface of the second hole H2 extends between the adjacent upper wirings 126 in contact with the first protrusion 132P, the lower surface 132PBS of the first protrusion 132P may have a flat shape. In addition, the upper surface 134PUS of the second protrusion 134P extending between the lower wirings 128, which are adjacent to each other and in contact with the second protrusions 134P, may have a flat shape.

As described above, the upper surface protection layer 132 may include the first protrusion 132P extending from the inside of the substrate base 110 toward the upper wiring 126, and the second protrusion 134P extending from the inside of the substrate base 110 of the lower surface protection layer 134 toward the lower wiring 128. In some example embodiments, the upper surface protection layer 132 may be engaged with the upper wiring 126. In some example embodiments, the lower surface protection layer 134 may be coupled with the lower wiring 128.

In some example embodiments, the upper surface protection layer 132 may be in contact with at least a portion of each of the side surfaces of the upper wiring 126, the lower surface of the upper wiring 126, and the upper surface of the upper wiring 126. In some example embodiments, the lower surface protection layer 134 may be in contact with at least a portion of each of the upper surface of the lower wiring 128, the side surfaces of the lower wiring 128, and the lower surface of the lower wiring 128.

Thus, the method of forming the printed circuit board 100 of FIG. 3 has been described. As described above, the upper surface protection layer 132 may be coupled with the upper wiring 126 and/or the lower surface protection layer 134 may be coupled with the lower wiring 128. Accordingly, the adhesion force between the upper surface protection layer 132 and the upper wiring 126 may be increased, and/or the adhesion force between the lower surface protection layer 134 and the lower wiring 128 may be increased. Thus, the reliability of the printed circuit board 100 may be increased.

In addition, in the process of forming the second hole H2 in FIG. 14, when the second hole H2 is formed to be apart from the upper wiring 126 and/or the lower wiring 128 in the vertical direction (Z direction) and a solder resist is doped thereon, the printed circuit board 100f of FIG. 9 may be formed.

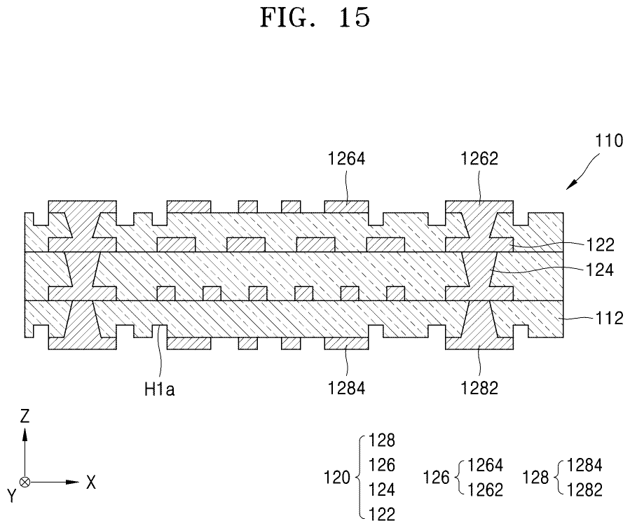

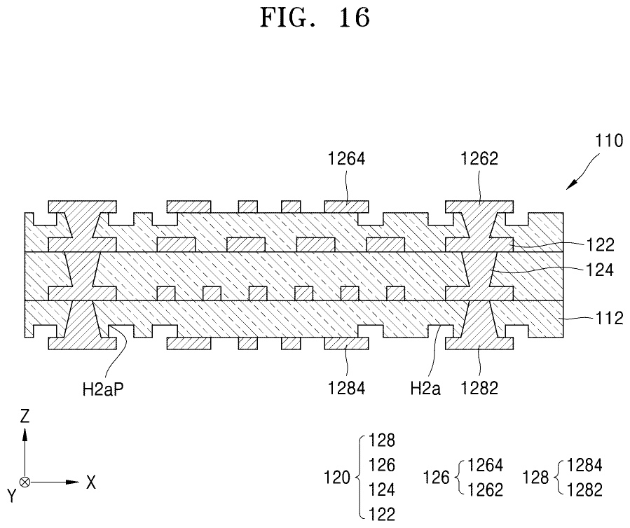

FIGS. 15 and 16 are cross-sectional views describing a method of manufacturing a printed circuit board, according to some example embodiments. FIGS. 15 and 16 are cross-sectional views describing a method of forming the printed circuit board 100a of FIG. 4. FIGS. 15 and 16 are described with reference to FIGS. 4 and 12 together.

Referring to FIG. 15, at least a portion of the base layer 112 may be removed from the resultant product of FIG. 12 to form a first hole H1a. Unlike the first hole H1 in FIG. 13, the first hole H1a may be formed only in a topical region near the upper wiring 126 and/or the lower wiring 128.

Side surfaces of the first hole H1a (e.g., side surfaces of the base layer 112 at least partially defining the first hole H1a) may extend in the vertical direction (Z direction). In some example embodiments, the side surfaces of the first hole H1a may be aligned (e.g., coplanar) with side surfaces of the upper wiring 126 and/or side surfaces of the lower wiring 128 in the vertical direction (Z direction). In some example embodiments, the side surfaces of the first hole H1a may be aligned with the side surfaces of the upper wiring 126 and/or the side surfaces of the lower wiring 128 in the horizontal direction (X direction and/or Y direction). In some example embodiments, the base layer 112 may include side surfaces at least partially defining the hole H1a extending in the vertical direction (Z direction) facing side surfaces that are aligned with side surfaces of the upper wiring 126 and/or side surfaces of the lower wiring 128.

FIG. 15 illustrates that the base layer 112 between the upper connection pad 1262 and the upper circuit pattern 1264 adjacent to each other is removed, or the base layer 112 between the lower connection pad 1282 and the lower circuit pattern 1284 adjacent to each other is removed, but the technical idea of the inventive concepts is not limited thereto.

For example, the base layer 112 between the upper circuit patterns 1264 adjacent to each other may be removed, or the base layer 112 between the lower connection pad 1282 and the lower circuit pattern 1284 adjacent to each other may be removed. In this case, the printed circuit board 100c of FIG. 6 or the printed circuit board 100e of FIG. 8 may be formed.

Referring to FIG. 16, after at least a portion of the base layer 112 is further removed, a second hole H2a may be formed. The removal process of at least a portion of the base layer 112 may be substantially the same as that performed with reference to FIG. 14, except that the first hole H1a is formed only in a region adjacent to the upper wiring 126 and/or the lower wiring 128.

In some example embodiments, at least a portion of the second hole H2a may overlap the upper wiring 126 and/or the lower wiring 128 in the vertical direction (Z direction). In a plan view, the second hole H2a may further include the first hole H1a and a protrusion cavity H2aP protruding in a direction where the upper wiring 126 and/or the lower wiring 128 are arranged. The protrusion cavity H2aP may extend in the horizontal direction (X direction and/or Y direction). The protrusion cavity H2aP may provide spaces for forming the first protrusion 132aP and/or the second protrusion 134aP in FIG. 4.

In some example embodiments, the second hole H2a may be in contact with (e.g., at least partially defined by) the lower surface of the upper wiring 126 and/or the upper surface of the lower wiring 128. The protrusion cavity H2aP of the second hole H2a may be in contact with (e.g., at least partially defined by) the lower surface of the upper wiring 126 and/or the upper surface of the lower wiring 128. In another example embodiment, the second hole H2a may be spaced apart from the lower surface of the upper wiring 126 and/or the upper surface of the lower wiring 128 in the vertical direction (Z direction). The protrusion cavity H2aP of the second hole H2a may be spaced apart from the lower surface of the upper wiring 126 and/or the upper surface of the lower wiring 128 in the vertical direction (Z direction). For example, in some example embodiments, a portion of the base layer 112 may extend between the protrusion cavity H2aP and a bottom surface of the upper wiring 126 or a top surface of the lower wiring 128. One surface of the second hole H2a (e.g., a surface of the base layer 112 at least partially defining the second hole H2a) extending in the horizontal direction (X direction and/or Y direction) inside the substrate base 110 may have an uneven shape. In addition, the side surfaces of the protrusion cavity H2aP (e.g., a side surface of the base layer 112 at least partially defining the protrusion cavity H2aP) may extend in the vertical direction (Z direction).

Thereafter, a solder resist may be doped on the inside of the second hole H2a, and on each of at least portions of the upper surface of the base layer 112 at the uppermost portion and/or the lower surface of the base layer 112 at the lowermost portion. The doping process of the solder resist may be substantially the same as that performed with reference to FIG. 14, except that a solder resist is doped inside the second hole H2a. A solder resist may be applied to each of at least a portion of the inside of the second hole H2a, the upper surface of the base layer 112 at the uppermost portion, and/or the lower surface of the base layer 112 at the lowermost portion, and the upper surface protection layer 132a and/or the lower surface protection layer 134a may be formed. The second holes H2a may be formed only in a region adjacent to the upper wiring 126 and/or the lower wiring 128, and may be adjacent to each other, and between the upper wirings 126 in contact with the first protrusion 132aP, the lower surface 132aPBS of the first protrusion 132aP may have an uneven shape. In addition, between the lower wirings 128, which are adjacent to each other and in contact with the second protrusions 134aP, the upper surface 134aPUS of the second protrusion 134aP may have an uneven shape.

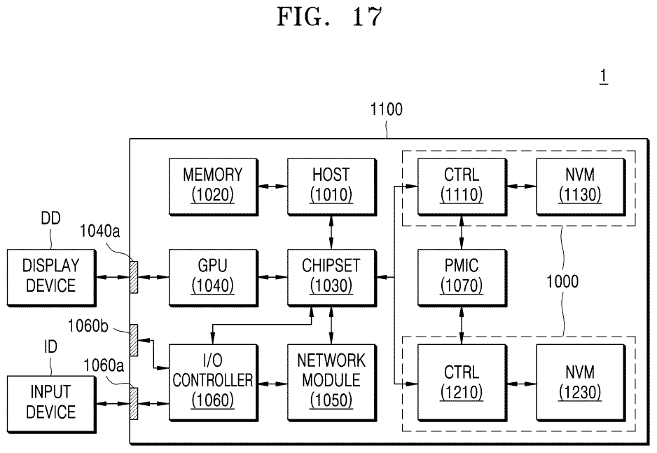

FIG. 17 is a block diagram of a computing system 1 including a semiconductor package according to some example embodiments.

Referring to FIG. 17, the computing system 1 may include various hardware configured as a semiconductor package.

The computing system 1 may include, for example, at least one of a computer, a portable computer, a tablet computer, a workstation, a server, a mobile phone, a digital camera, a device capable of transceiving information in a wired/wireless environment, and an electronic device constituting a home network system. The computing system 1 may include the main board 1100 on which various hardware is mounted, a display device DD, and an input device ID.

The storage device 1000, the host 1010, the memory 1020, the chipset 1030, the graphics processing device 1040, the network module 1050, an input/output (I/O) controller 1060, a plurality of I/O sockets 1040a, 1060a, and 1060b, and a power management integrated circuit (PMIC) 1070 included in the computing system 1 may be mounted in each dedicated region provided on the main board 1100.

Various hardware required to operate the computing system 1 may be mounted on the main board 1100. In some example embodiments, the main board 1100 may include dedicated regions in which various hardware, such as a semiconductor package, a semiconductor device, a passive device, an active device, a control circuit, and/or an electronic circuit are respectively mounted.

The main board 1100 may include various wirings. The various wirings may electrically connect various hardware mounted on the main board 1100, respectively. Various hardware mounted on the main board 1100 may communicate with each other via various wires.

The storage device 1000 may include controllers CTRLs 1110 and 1210 and non-volatile memories NVMs 1130 and 1230. Of course, the number of storage devices mounted on the main board 1100 is not limited thereto.

The controllers CTRLs 1110 and 1210 may respectively control the non-volatile memories NVMs 1130 and 1230 according to a command from the host 1010. For example, the controllers CTRLs 1110 and 1210 may read data stored in the non-volatile memories NVMs 1130 and 1230 or program data in the non-volatile memories NVMs 1130 and 1230 according to a command from the host 1010, respectively. In some example embodiments, the controllers CTRLs 1110 and 1120 may communicate with the host 1010 via the chipset 1030.

The storage device 1000 may be used as a large capacity storage medium of the computing system 1. In some example embodiments, the non-volatile memories NVMs 1130 and 1230 may constitute a redundant array of independent disks (RAIDs).

As described above, the controllers CTRLs 1110 and 1120 and the volatile memories NVMs 1130 and 1230 of the storage device 1000 may be mounted on the main board 1100. In other words, the storage device 1000 may include an on-board storage medium or an on-board solid state drive (SSD).

The host 1010 may perform all operations required for the computing system 1 to operate. For example, the host 1010 may interpret a command input by a user, perform a computation operation based on the interpreted command, and process data. The host 1010 may be referred to as a CPU.

The memory 1020 may be used as a main memory of the computing system 1. The memory 1020 may include a volatile memory, such as DRAM, SRAM, and double data rate (DDR) DRAM. In an embodiment, the memory 1020 may be mounted on the main board 1100, and may be electrically connected to the host 1010 via a wiring provided to the main board 1100.

The chipset 1030 may be a device which controls various hardware included in the computing system 1 according to a command from the host 1010. For example, the chipset 1030 may control the storage device 1000, the graphics processing device 1040, the network module 1050, and the I/O controller 1060 according to the command of the host 1010.

In some example embodiments, the chipset 1030 may be mounted on the main board 1100, and may be electrically connected to various hardware via wirings provided to the main board 1100. In addition, the chipset 1030 may communicate with various hardware via preset interfaces. For example, the preset interfaces may include at least one of various interfaces, such as universal serial bus (USB), peripheral component interconnection (PCI), advanced technology attachment (ATA), small computer system interface (SCSI), enhanced small disk interface (ESDI), integrated drive electronics (IDE), Firewire, universal flash storage (UFS), and/or inter-integrated circuit (I2C).

The graphics processing device 1040 may convert a result of a computation operation or data, which has been processed by the host 1010, into an image signal. The converted image signal may be output by the display device DD. In some example embodiments, the graphics processing device 1040 may be mounted on the main board 1100, and may be connected to the chipset 1030 and a connector 1040a via wirings provided on the main board 1100. In some example embodiments, the graphics processing device 1040 may also be included in the host 1010. In addition, the connector 1040a may be directly connected to the display device DD.

The network module 1050 may support wired or wireless communication with the outside of the computing system 1. For example, the network module 1050 may support wireless communications, such as code-division multiple access (CDMA), global system for mobile communication (GSM), wireless communication CDMA (WCDMA), time division multiplexing access (TDMA), long term evolution (LTE), Bluetooth, and wireless fidelity (WiFi). In some example embodiments, the network module 1050 may be mounted on the main board 1100, and may be connected to the chipset 1030 via a wiring provided on the main board 1100.

The I/O controller 1060 may process information input from the input device ID or may control connectors 1060a and 1060b. The I/O controller 1060 may be connected to the connectors 1060a and 1060b to manage them. In some example embodiments, the I/O controller 1060 may be mounted on the main board 1100, and may be connected to the connectors 1060a and 1060b via the wirings provided to the main board 1100. For example, the connectors 1060a and 1060b may include at least one of various I/O terminals, such as a personal system (PS) 2 port, a peripheral component interconnection (PCI) slot, a dual in-line memory module (DIMM) slot, a universal serial bus (USB) terminal, a red/green/blue (RGB) port, a digital visual interface (DVI) port, and a high-definition multimedia interface (HDMI) port.

A power management chip 1070 may supply power to various hardware of the computing system 1, based on power provided from the outside. For example, the power management chip 1070 may supply power to the storage device 1000. In some example embodiments, the power management chip 1070 may provide dedicated power for the storage device 1000.

While the inventive concepts have been particularly shown and described with reference to some example embodiments thereof, it will be understood that various change in form and details may be made therein without departing from the spirit and scope of the following claims.

What is claimed is:

1. A printed circuit board comprising:
a substrate base including a first surface and a second surface opposite to the first surface;
a wiring on the first surface of the substrate base; and
a protection layer configured to cover at least a portion of the first surface of the substrate base, the protection layer is configured expose at least a portion of the wiring, wherein
the protection layer includes a body and a protrusion connected to the body, the protrusion is configured to protrude toward the wiring inside the substrate base, and
the protrusion overlaps at least a portion of the wiring in a vertical direction.

2. The printed circuit board of claim 1, wherein the protrusion is in contact with at least a portion of the wiring.

3. The printed circuit board of claim 1, wherein the protrusion is spaced apart from the wiring in the vertical direction.

4. The printed circuit board of claim 1, wherein the protection layer is in contact with side surfaces of the wiring.

5. The printed circuit board of claim 1, wherein the protection layer is coupled with the wiring.

6. The printed circuit board of claim 1, wherein
the wiring includes a connection pad at least partially exposed by the protection layer and a circuit pattern covered by the protection layer, and
the protrusion overlaps at least one of the connection pad or the circuit pattern in the vertical direction.

7. The printed circuit board of claim 6, wherein, in a plan view, the protrusion surrounds at least a portion of the connection pad.

8. A printed circuit board comprising:
a substrate base including a first surface and a second surface opposite to the first surface;
a first wiring on the first surface of the substrate base;
a second wiring on the second surface of the substrate base;
a first protection layer configured to cover at least a portion of the first surface of the substrate base, the first protection layer is configured to expose at least a portion of the first wiring; and
a second protection layer configured to cover at least a portion of the second surface of the substrate base, the second protection layer is configured to expose at least a portion of the second wiring, wherein
the first wiring includes a first connection pad at least partially exposed by the first protection layer and first circuit patterns covered by the first protection layer,
the first protection layer includes a first body and a protrusion connected to the first body, the protrusion is configured to protrude from an inside of the substrate base toward the first wiring, and
the protrusion overlaps at least a portion of the first wiring in a vertical direction.

9. The printed circuit board of claim 8, wherein the first protection layer is in contact with at least a portion of each of a lower surface of the first wiring, side surfaces of the first wiring, and an upper surface of the first wiring.

10. The printed circuit board of claim 9, wherein the protrusion is in contact with at least a portion of each of the first connection pad and the first circuit patterns, the first connection pad and the first circuit patterns are adjacent to each other.

11. The printed circuit board of claim 9, wherein the protrusion is in contact with at least two of the first circuit patterns adjacent to each other.

12. The printed circuit board of claim 8, wherein, in a cross-sectional view, the protrusion is arranged closer to a central axis of the substrate base in the vertical direction than each of the first wiring and the second wiring, the central axis of the substrate base extending in a horizontal direction.

13. The printed circuit board of claim 8, wherein, in a plan view, the protrusion surrounds at least a portion of an outer surface of the first connection pad.

14. The printed circuit board of claim 8, wherein, in a plan view, the protrusion surrounds an entirety of an outer surface of the first connection pad.

15. The printed circuit board of claim 8, wherein the first protection layer is coupled with the first connection pad.

16. The printed circuit board of claim 8, wherein
the protrusion includes a first protrusion and a second protrusion, the first protrusion is in contact with at least a portion of each of the first connection pad and the first circuit patterns, and
the second protrusion is in contact with at least two of the first circuit patterns adjacent to each other.

17. A semiconductor package comprising:
a printed circuit board; and
a semiconductor chip mounted on the printed circuit board, the printed circuit board including
a substrate base including one or more base layers, the substrate base including a first surface and a second surface opposite to the first surface;
a first wiring on the first surface of the substrate base;
a second wiring on the second surface of the substrate base;
a first protection layer configured to cover at least a portion of the first surface of the substrate base, the first protection layer is configured to expose at least a portion of the first wiring; and
a second protection layer configured to cover at least a portion of the second surface of the substrate base, the second protection layer is configured to expose at least a portion of the second wiring, wherein
the first protection layer includes a first body and a first protrusion connected to the first body, the first protrusion is configured to protrude from an inside of the substrate base toward the first wiring, and
the first protrusion overlaps at least a portion of the first wiring in a vertical direction.

18. The semiconductor package of claim 17, wherein the second protection layer includes a second body and a second protrusion connected to the second body, the second protrusion is configured to protrude from an inside of the substrate base toward the second wiring.

19. The semiconductor package of claim 17, wherein
the first protection layer surrounds the first wiring, and
the second protection layer surrounds the second wiring.

20. The semiconductor package of claim 17, wherein
the first protection layer is coupled with the first wiring, and
the second protection layer is coupled with the second wiring.
